(19) United States
(12) Patent Application Publication
(10) Pub. No.: US 2015/0140267 A1
(43) Pub. Date: May 21, 2015

(54) SURFACE PREPARATION METHOD

(71) Applicants: Christophe Navarro, Bayonne (FR); Karim Aissou, Gradignan (FR); Cyril Brochon, Merignac (FR); Stefan Dilhaire, Talence (FR); Guillaume Fleury, Bordeaux (FR); Stephane Grauby, Bordeaux (FR); Georges Hadziioannou, Leognan (FR); Jean-Michel Rampnoux, Pessac (FR); Jonah Shaver, Bordeaux (FR)

(72) Inventors: Christophe Navarro, Bayonne (FR); Karim Aissou, Gradignan (FR); Cyril Brochon, Merignac (FR); Stefan Dilhaire, Talence (FR); Guillaume Fleury, Bordeaux (FR); Stephane Grauby, Bordeaux (FR); Georges Hadziioannou, Leognan (FR); Jean-Michel Rampnoux, Pessac (FR); Jonah Shaver, Bordeaux (FR)

(73) Assignees: Arkema France, Colombes (FR); Universite de Bordeaux, Bordeaux (FR)

(21) Appl. No.: 14/402,957

(22) PCT Filed: May 23, 2013
(86) PCT No.: PCT/FR2013/051119

§ 371 Date: Nov. 21, 2014

Related U.S. Application Data
(60) Provisional application No. 61/651,080, filed on May 24, 2012.

(30) Foreign Application Priority Data
May 23, 2012 (FR) 12.54685

(51) Int. Cl. G03F 7/20; G03F 7/038; G03F 7/16

(52) U.S. Cl. CPC G03F 7/20; G03F 7/168; G03F 7/0388
USPC 428/141; 428/172; 430/322

(57) ABSTRACT

The invention relates to a process for the preparation, by spatial distribution of light intensity, of a surface in relief promoting order and spatial coherence serving as a guide for the organization, on nano- and micrometre scales, of an overlayer on the surface in particular of block copolymers.

The invention relates to a process for the preparation, by spatial distribution of light intensity, of a surface in relief promoting order and spatial coherence, serving as a guide for the organization, on nano- and micrometre scales, of an overlayer on the surface, in particular of block copolymers.

Because of their capacity for nanostructuring, the use of block copolymers in the fields of electronics and optoelectronics is now well known. This is in particular illustrated in the article by Cheng et al. (ACS nano, Vol. 4, No. 8, 4815-4823, 2010). It is possible to structure and guide the arrangement of the domains inherent to the segregation of block copolymers on scales of less than 50 nm, while very strongly limiting the density of defects in organization.

The desired structuring (for example generation of domains perpendicular to the surface with no defect in the ordered arrangement) nevertheless requires the preparation of the support on which the block copolymer is deposited in order to control the arrangement of the domains while eliminating the defects (disclinations, dislocations, and the like). Among the possibilities known, two techniques are more particularly used: physical epitaxy (graphoepitaxy) and chemical epitaxy. They are both based on the production of a network of motifs (topographical and chemical/surface, respectively) having a higher periodicity than that of the block copolymer but possessing commensurability with it. The self-assembly of block copolymers into thin films on this type of surface then leads to a two-dimensional network having no defects (single grain).

These techniques, which are widely described in the literature, allow the arrangement of the block copolymers on large surfaces without producing defects. However, the use of these techniques is long and expensive.

The applicant has discovered that a surface coated with a (co)-polymer comprising isomerizable functional groups allowed, after exposure to a spatial distribution of light intensity, the creation of motifs in relief. These motifs allow the deposition of block copolymers with a structuring free of defects, when the thickness of the block copolymer layer coating the surface in reliefs is neatly adjusted, this being in short periods of time and at low cost. According to an advantageous variant of the invention, the (co)-polymer comprising the isomerizable functional groups comprises crosslinkable functional groups. This is particularly useful when the solution containing the block copolymer is liable to solubilize the (co)-polymer containing the isomerizable functional groups. In the opposite case, that is to say when the solution of block copolymer does not solubilize the (co)-polymer comprising isomerizable functional groups, it is not necessary to have crosslinkable functional groups on the (co)-polymer comprising isomerizable functional groups.

The process of self-assembly of the block copolymers on a treated surface according to the invention is governed by thermodynamic laws. For example, when the self-assembly leads to a morphology of the cylindrical type having a P6/mm type symmetry, each cylinder is surrounded by 6 equidistant neighbouring cylinders if there are no defects. For a cylindrical morphology possessing a P4/mm type symmetry, each cylinder is surrounded by 4 equidistant neighbouring cylinders if there are no defects. There are several ways of quantifying the presence of defects within the copolymer film. The first way consists of directly counting the number of topological defects within the film by evaluating the number of nearest neighbours around the domain considered. For example, in the case of a morphology of the cylindrical type possessing a P6/mm type symmetry, if four, five or seven cylinders surround the domain considered, it will be considered that there is a defect. The second way of finding out the degree of self-organization of the 2D network within the block copolymer film consists in evaluating the average distance between the domains surrounding the domain considered, by establishing the function of distribution of the distance to the nearest neighbour of the domain centres. Indeed, the Lindemann criterion which was originally formulated for 3D systems refers to an onset of melting of the lattice (passage to the liquid state) when the square root of the displacement of the nanodomains, [symbol] u(r)² [symbol] ^{1/2} where r defines the position of the centre of the nanodomain, exceeds 10% of the lattice period, p. By modifying this criterion, it becomes possible to apply it to 2D systems although the latter do not possess a long-range order. Thus, because of the divergence mentioned, the mean square deviation of the displacements of two adjacent domains, [symbol] (u(r+p)−u(r))² [symbol] which, by definition, is equal to the variance σ², is preferred to it. [W. Li, F. Qiu, Y. Yang, and A. C. Shi, Macromolecules 43, 1644 (2010); K. Aissou, T. Baron, M. Kogelschatz, and A. Pascale, Macromol. 40, 5054 (2007); R. A. Segalman, H. Yokoyama, and E. J. Kramer, Adv. Matter. 13, 1152 (2003); R. A. Segalman, H. Yokoyama, and E. J. Kramer, Adv. Matter. 13, 1152 (2003)]. To determine the topological defects, the combined Voronol diagrams and/or the Delaunay triangulations are conventionally used. After binarization of the image, the centre of each domain is identified. The Delaunay triangulation and/or the Voronol diagram then makes it possible to identify the number of first order neighbours while the function of distribution of the distance to the nearest neighbour of the domain centres makes it possible to quantify the mean deviation between two nearest neighbours. It is thus possible to quantify the number of defects. This method of counting is described in the article by Tiron et al. (J. Vac. Sci. Technol. B 29(6), 1071-1023, 2011).

### SUMMARY OF THE INVENTION

The invention relates to a process for the preparation, by spatial distribution of light intensity, of a surface in relief promoting order and spatial coherence serving as a guide for the organization, on nano- and micrometre scales, of an overlayer on the surface comprising the following steps:
A: Deposition of a solution or dispersion of at least one (co)-polymer containing at least one isomerizable functional group on a surface.
B: Evaporation of the solvent.
C: Irradiation of the surface thus treated according to a spatial distribution of light intensity and creation of motifs possessing a periodic or non-periodic relief.
D: Deposition of a solution or a dispersion on the surface thus treated, of at least one nano-object, consisting of an assembly of atoms, of which at least one of the three dimensions is less than the half-wavelength used for the irradiation of the surface.
E: Removal of the solvent by evaporation or reaction.

### DETAILED DESCRIPTION

The expression nano-object is understood to mean an assembly of atoms, of which at least one of the three dimensions is less than the half-wavelength used for the irradiation of the surface. This may consist of particles, which may be organic, inorganic or organic/inorganic hybrids. The inorganic particles may be magnetic particles such as iron-platinum particles. The organic particles may be liquid crystal molecules, or molecules crystallizing by surface epitaxy, but also (co)-polymer core-shell structures, polymer or nonpolymer vesicles, (co)-polymer or non-(co)-polymer micelles. The expression nano-object is also understood to mean (co)-polymers capable of becoming organized, such as liquid crystal (co)-polymers, (co)-polymers capable of becoming organized by crystallizing periodically, block copolymers capable of self-organizing. Preferably, the nano-objects are block copolymers. The expression dimension is understood to mean the size corresponding to the step of organization of the nano-object into domains, when this consists for example of block copolymers. A precise definition of nano-objects is also given by the ISO/TS 27687 standard: 2008: 2008-08.

The (co)-polymers containing isomerizable bonds and, where appropriate, crosslinkable functional groups used in the invention may be of any type. They contain at least one functional group that is isomerizable under the effect of an external energy supply. They may also contain at least one functional group allowing the crosslinking of the copolymer under the effect of an energy supply. In the latter case, an additional step C′ should be added after step C consisting in crosslinking the (co)-polymer containing at least one isomerizable functional group and at least one crosslinkable functional group. Preferably, the isomerizable functional groups and the crosslinkable functional groups are pendant to the main chain. The expression isomerizable functional group is understood to mean a functional group whose configuration can change from cis to trans or from trans to cis. This may be for example an azo functional group or a carbon-carbon double bond. The chromophoric entities containing these double bonds may be chosen from azobenzenes, aminostilbenes, pseudo-stilbenes, diaryl-alkenes. These isomerizable entities are preferably stimulatable with the aid of appropriate monochromatic irradiation whose wavelength corresponds to the absorption bands of the chromophore. Preferably, they are azobenzene entities.

(Co)-polymers containing isomerizable and crosslinkable bonds which are used in the invention have weight-average molecular masses of 500 to 1000000 g/mol with a preference around 10000 g/mol.

The expression crosslinkable functional group is understood to mean a functional group present on the (co)-polymer which makes it possible to create a bond between the chains of the (co)-polymer constituting the “guiding” surface. This functional group may be a carbon-carbon double bond or a functional group which makes it possible to create a bond between the chains such as a hydroxy, epoxy, amine, acid, anhydride, aldehyde, urea or isocyanate functional group. Preferably, this may be a carbon-carbon double bond such as acrylic, methacrylic, vinyl. Preferably still, it is a methacrylic functional group. The crosslinking may be improved in the presence of a multifunctional monomer, such as divinylbenzene, butanediol dimethacrylate, triallylcyanurate. Preferably, it is tris((2-acryloyloxy)ethyl)isocyanurate. A photoinitiator is used to initiate the crosslinking which absorbs in a range of wavelength whose absorption spectrum is not superimposable on that of the chromophore(s) used. In particular, the wavelength corresponding to the absorption maximum of the photoinitiator should not be superimposable on that of the chromophore.

There may be mentioned, without limitation, cyanines, benzophenone, acetophenone, benzoin or 2-hydroxy-1,2-di(phenyl)ethanone, ethers derived from benzoin such as benzoin ethanoate, benzil or 1,2-diphenylethanedione, benzil acetals such as benzil α,α-dimethyl acetal, acylphosphine oxides, thioxanthones and derivatives thereof, fluorene, pyrene, methylene blue, thionine and in particular thionine acetate, fluorescein, eosin. It is also possible to initiate the polymerization (crosslinking of the three-dimensional lattice) by the thermal route.

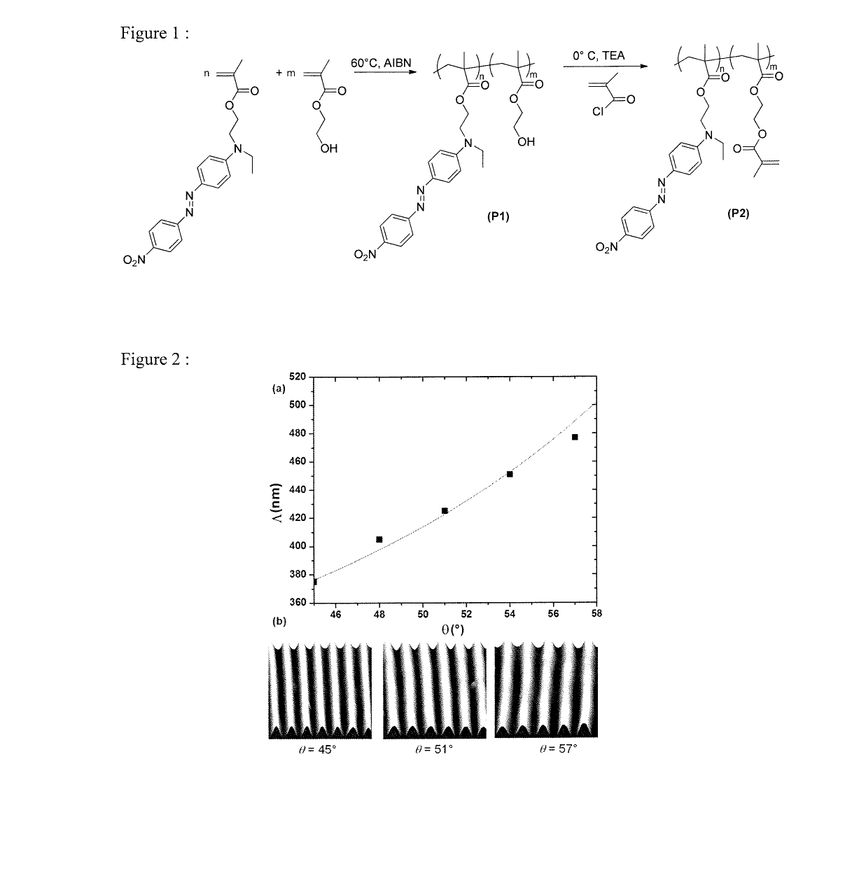

The synthesis of the (co)-polymers containing isomerizable bonds and optionally crosslinkable functional groups may be carried out in any manner known to a person skilled in the art. A typical example of a synthesis scheme is given in FIG. 1.

The (co)-polymers containing isomerizable bonds, and optionally crosslinkable functional groups, containing, where appropriate, in addition a multifunctional monomer, and, where appropriate, a photoinitiator are then dissolved in a suitable solvent. Next, the solution is deposited on a surface. The surface may be of any type, but a surface is preferably chosen which is useful for electronic applications such as silicon, oxidized or non-oxidized silica, silica exhibiting a surface treatment, such as one or more layers that are anti-reflective or that are of high reflectivities, carbon exhibiting a surface treatment or not, polymer-based flexible films, (co)-polymers, titanium nitride. Once deposited on the surface, the deposited solution is subjected to evaporation of the solvent.

The surface is then structured according to a given topography by a distribution of light intensity, typically monochromatic at a wavelength corresponding to the absorption bands of the chromophore. Depending on the type of interferences chosen, it is thus possible to create 3D motifs inherent to the spatial distribution of light intensity. The spatial distribution of light intensity is obtained:
full field by an interference figure. The full field approach makes it possible to obtain on a surface simple motifs such as lines or concentric circles by the use of refractive optical devices (lenses) or of reflective optical devices (mirrors). More complex motifs may be obtained with a holographic optical device, or by multiplying the passages.
localized by displacing a monochromatic beam focussed on the surface. Thus, any motif may be obtained.
by combining the spatial light distribution of full field or localized light intensity.

In all cases, the resolution is limited to the half-wavelength of the source creating the spatial distribution of light intensity.

When the (co)-polymer contains crosslinkable functional groups, the surface thus treated is then subjected to a second irradiation at a wavelength allowing crosslinking of the copolymer, which makes it possible to immobilize the motifs previously created.

A solution or dispersion of at least one nano-object is then deposited on this treated surface and the solvent is then evaporated. It is also possible to carry out solvent or thermal annealing in order to obtain a thermodynamically metastable or stable state for the nano-object(s).

When the nano-objects are block copolymers, they are of the di-block, tri-block or multi-block type, with a linear architecture, or a comb-shaped, or star-shaped or dumb-bell-shaped, and a mixture thereof, including the homopolymer of each of the blocks. Preferably, they are di-block copolymers. According to a second preference, they are tri-block copolymers. The block copolymers may contain random or gradient sequences between the actual blocks and they consist of blocks containing at least two blocks that are not miscible with each other. If the case of a di-block AB is considered, which corresponds to an assembly of 2 chains A and B bonded together by a covalent bond, the chemical incompatibility between the blocks allows a phenomenon called “phase microseparation” based on repulsive interactions between blocks. The block copolymers considered known, without limitation, to exhibit this phenomenon are polystyrene-b-poly(methyl methacrylate) PS-b-PMMA, polystyrene-b-polybutadiene PS-b-PB, polystyrene-b-polyisoprene PS-b-PI, polystyrene-b-poly(ethylene oxide) PS-b-PEO, polystyrene-b-poly(dimethylsiloxane) PS-b-PDMS, polystyrene-b-poly(lactic acid) PS-b-PLA, polystyrene-b-poly(4-vinylpyridine) PS-b-P4VP, polystyrene-b-poly(2-vinylpyridine) PS-b-P2VP, polybutadiene-poly(methyl methacrylate) PB-b-PMMA, poly(methyl methacrylate)-b-poly(butyl acrylate)-b-poly(methyl methacrylate) PMMA-b-PABu-b-PMMA, polystyrene-b-polybutadiene-b-poly(methyl methacrylate), PS-b-PB-b-PMMA, poly(dimethylsiloxane)-b-poly(lactic acid), PLA-b-PDMS, poly(lactic acid)-b-poly(dimethylsiloxane)-b-poly(lactic acid), PLA-b-PDMS-b-PLA. Preferably, they are PS-b-PMMA, PS-b-PEO, PDMS-b-PS, PLA-PDMS-b-PLA. The thickness of the block copolymer layer should be sufficient, typically such that the topographic relief created by the (co)-polymer containing isomerizable functional groups is no longer visible by AFM microscopy (atomic force microscopy), without however exceeding this optimum. Organization of the block copolymer is thereby obtained according to a precise topography and free of defects. The block copolymers may contain at least one degradable block. The expression degradable is understood to mean the chemical elimination or transformation of the block(s) considered by treatment with an acid or base solution, or alternatively by plasma treatment. The acid or base treatments may also be combined with a plasma treatment when the block copolymer contains at least one block that is degradable by an acid or base route and a block that is degradable by the plasma route.

The process of the invention is used for the manufacture of surfaces useful in applications for holographic optical components, for the volume storage of data, for the production of surfaces or materials exhibiting photo-controlled deformation, for the creation of nanoporous or microporous structures, for example, for filtration membranes or for batteries, for surface coating in order to obtain, for example, super-hydrophobic surfaces, variegated surfaces, antireflective surfaces, surfaces exhibiting an opalescent effect, for the creation of optical or Plasmon waveguides on substrates, for the control of the transport properties of materials (electronic, acoustic, thermal, electromagnetic and the like), for the production of templates on the nanometre scale, or as assembly guide for block copolymers on a surface serving in particular as lithography mask.

### EXAMPLES

### Example 1

The general scheme for the production of the isomerizable and crosslinkable (co)-polymer P2 is shown in FIG. 1.

The copolymer P1 is obtained by free-radical polymerization. To a Schlenk tube are added 10 ml of tetrahydrofuran (THF), 32.5 mg of hydroxyethyl methacrylate, 300 mg of N-ethyl-N-(2-hydroxyethyl)-4-(4-nitrophenylazo)aniline methacrylate (CAS No. 103553-48-6) (DR1M) and 2,2′-azobis-(2-methylpropionitrile) (AIBN), (7 mol % relative to the number of moles of monomers). The solution is degassed with nitrogen for 5 minutes. The tube is then sealed and heated with constant stirring at 60° C. for 48 hours. The copolymer is then isolated by precipitation with methanol, and then filtered and dried under vacuum at 60° C. for 24 hours. The copolymer was characterized by proton NMR and its weight-average molecular mass (Mw) evaluated by size exclusion chromatography (SEC) calibrated with polystyrene standard samples (Mw=10000 g/mol, Vp=1.8, fₘₒₗ(HEMA)=0.22 and fₘₒₗ(DR1M)=0.78 in which Vp is the dispersity of the polymer and fₘₒₗ the molar fraction.

The copolymer P2 is obtained by esterification of the polymer P1 with methacryloyl chloride. The reaction is carried out in the presence of N,N,N-triethylamine (TEA). 200 mg of the polymer P1 are introduced into a 50 ml round-bottomed flask supplemented with 15 ml of THF. The round-bottomed flask is cooled to 0° C. on an ice bath, and then 1 ml of TEA and 12.3 mg of methacryloyl chloride are introduced. After one hour, the ice bath is removed and the reaction continues at room temperature for 12 hours. The copolymer P2 is precipitated from pentane, filtered and then dried under vacuum at room temperature. The characteristics of the copolymer P2 are Mw=10500 g/mol, Vp=1.7, fₘₒₗ(HEMA)=0.24 and fₘₒₗ(DR1M)=0.76.

### Example 2

### Creation of a Sinusoidal Motif of the Copolymer P2 Deposited on a Substrate

A solution containing 3% by weight of the copolymer P2, tris((2-acryloyloxy)ethyl) isocyanurate (2.5 mol % relative to the number of acrylate functional groups on the copolymer P2) and the photoinitiator, cyanine H-Nu 640 from Spectra Group Ltd (3 mol % relative to the total number of acrylate functional groups) in THF is deposited on a silica plate by spin-coating. Using a Lloyd interferometer, a lattice of parallel lines is then induced whose sinusoidal topographic profile is proportional to that of the monochromatic illumination. A wavelength λw of 532 nm corresponding to the azobenzene chromophore absorption band is chosen in order to induce the trans-cis transition. The steps of the photo-inscribed motif Λ are adjusted by varying the angle of incidence θ of the beam for writing on the film (FIG. 2). The crosslinking of the layer of copolymer P2 is obtained by insolation of the photo-inscribed motif at a wavelength λf of 686 nm, non-resonant with the absorption of the azobenzene chromophore.

FIG. 2 (a) shows the variation of Λ as a function of θ. The square experimental points are obtained by extracting Λ from 2D Fourier transform corresponding to the AFM topographic image of the sinusoidal motif. The experimental points are in agreement with the theoretical curve corresponding to the equation Λ=λ_{w}/2 sin θ.

FIG. 2(b) is one of the AFM-3D images (2.5×2.5 μm) of a topographic view of the sinusoidal motifs obtained for various angles θ. There are 7, 6 and 5 peaks when the angle of incidence of the beam θ is equal to 45°, 51° and 57°, respectively.

### Example 3

### Deposition of a Di-Block Copolymer on the Surface Treated in Example 2

There is deposited by spin-coating on the surface treated in Example 2 a solution at 1% by mass, in benzene, of a polystyrene-poly(ethylene oxide) (PS-PEO) di-block copolymer having a number-average molecular mass of 43 kg/mol (M_{PS}=32 kg/mol, M_{PEO}=11 kg/mol, f_{PEO}=0.24, and M_{w}/Mₙ=1.06) measured by SEC and standardized with standard polystyrene samples. The dilution solvent is then evaporated and then annealing in a benzene vapour is then carried out in order to promote self-organization of the block copolymer on the 3D surface.

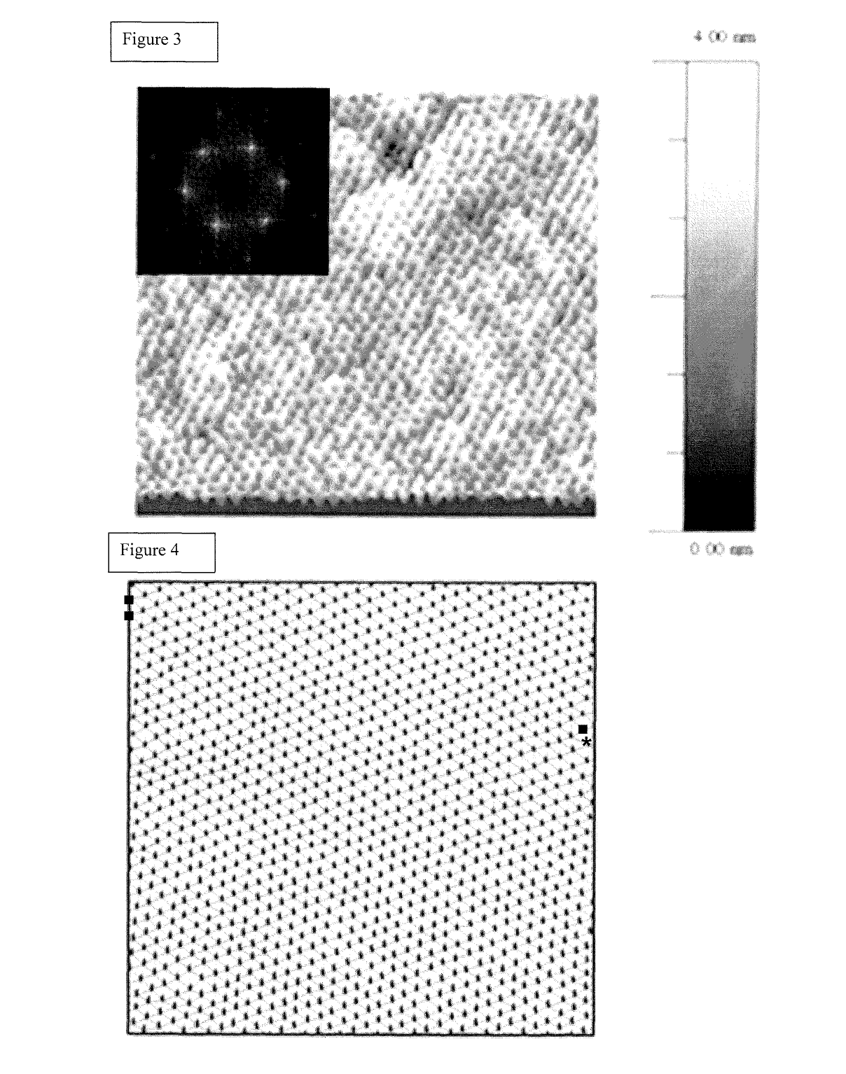

FIG. 3 shows a (1.25×1.25 μm) topographic AFM image of a thin film of PS-b-PEO self-organized on a surface having a sinusoidal profile according to the process of the invention.

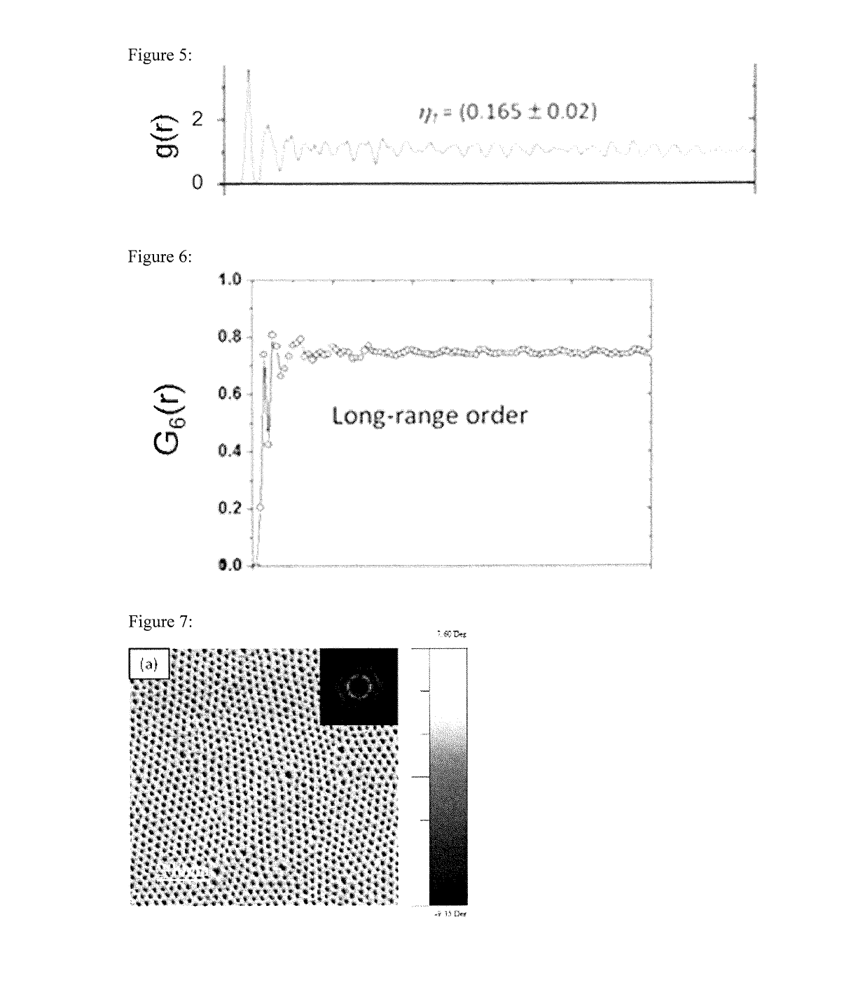

For the optimal thickness condition of the film of PS-b-PEO (t˜70 nm) (i.e. the free surface of the latter no longer exhibits periodic roughness related to the conformal deposition of the layer of PS-b-PEO on the periodic surface), the thin layer contains regions free from topological defects over distances ranging up to and beyond one square micron, as the associated Delaunay triangulation in FIG. 4 attests. This mathematical function, established from the centre of gravity of each of the cylinders as extracted by binarization of the grey level AFM image, makes it possible to determine the number of nearest neighbours of each cylinder with the following code: round point=6 neighbours, square point=5 neighbours, and star-shaped point=7 neighbours. In addition, the presence of 6 very narrow first-order peaks and the presence of second- and third-order peaks clearly defined in the fast Fourier transform (FFT) (see insert in FIG. 3) indicates the formation of a single grain with a hexagonal symmetry. In order to quantify the two-dimensional order of the thin film present in FIG. 3, the positional order was evaluated using a correlation pair function, g(r), (see FIG. 5), defined as the probability of finding a pore centre at a distance, r, from the pore centre in question whereas the orientational order was measured using an orientational correlation function, G₆(r), (see FIG. 6), defined in terms of the angle, φ, of the bonds (fictional lines) formed with its nearest neighbours (see attached appendix for the mathematical definition of the functions g(r) and G₆(r)). The results show that the envelope of the function g(r) is correctly adjusted with a decreasing power function whereas that of G₆(r)=constant. The interpretation of these results according to the Kosterlitz-Thouless-Halperin-Nelson-Young (KTHNY) theory (see Table 1 below) indicates the presence of a two-dimensional crystal order.

TABLE 1
criteria of the KTHNY theory, applied to g(r) and
G₆(r), allowing the various phases to be distinguished. ξₚ and
ξ₆ represent the orientational and positional correlation
lengths.

| | Crystal | Hexatic | Isotropic |
|---|---|---|---|
| | phase | phase | phase |
| g(r) | g(r) ~ r^{-η} | g(r) ~ exp(−r/ξp) | g(r) ~ exp(−r/ξₚ) |
| | where: | | |
| | 0 < η ≦ ⅓ | | |
| G₆(r) | G₆(r) ≡ 1 | G₆(r) ~ r^{-η} | G₆(r) ~ exp(−r/ξ₆) |
| | | where: | |
| | | 0 < η ≦ ¼ | |

The function g(r) may be expressed in the following way:

$$g ( r ) = \frac{1}{{ρ}^{2}} 〈 {\sum }_{i} {\sum }_{j \neq i} δ ( {r}_{i} ) δ ( {r}_{j} - r ) 〉 \qquad ( Eq . 1 )$$

where ρ, the average pore density, normalizes the function g(r) so that it tends asymptotically to unity (g(∞)→1) and δ is the Kronecker symbol.

The function G₆(r) is expressed in the following way:

G₆(r)≡ [symbol] ψ₆*(r)ψ₆(0) [symbol] /G_{B}(r) (eq. 2)

where ψ₆(r), the order parameter of the orientational bonds, is defined as:

$${ψ}_{6} ( r ) ≡ {\sum }_{{r}_{jk}}^{ } δ ( r - {r}_{jk} ) exp ( 6 {iφ}_{jk} ) \qquad ( Eq . 3 )$$

and G_{B}(r), the self-correlation function of the density of the bonds, normalizes G₆(r) to unity in the case of a perfect 2D lattice. In Equation 3, the rⱼₖ are the position vectors of the centres of the bonds and the φⱼₖ are the bond angles relative to the x-axis of the AFM image. In the case of a perfect hexagonal lattice, G₆(r) is equal to unity for all r.

### Example 4 Comparative

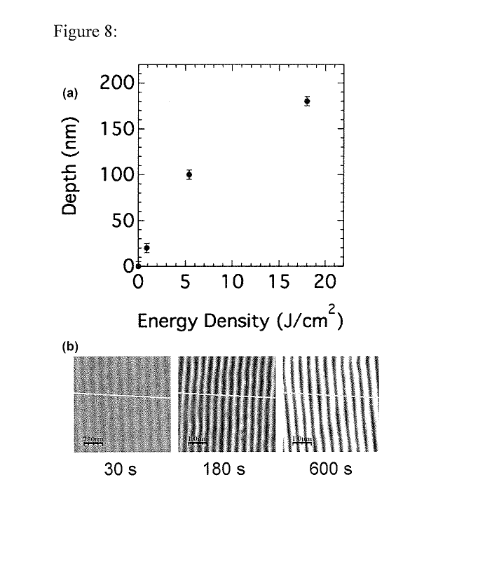

Example 4 is characteristic of the result obtained during self-organization of the same di-block copolymer on a surface not treated according to the process of the invention (FIG. 7 corresponds to an AFM image in self-organization phase mode characteristic of PS-b-PEO without the use of a prepared surface). Numerous defects are seen therein.

### Example 5

In this example, the time required to create the topographic motif as well as its depth are visualized, FIGS. 8 (a) and (b) as well as the AFM image of the motif created. The preparation of the surface according to the process of the invention occurs in 600 seconds, which is a lot faster than the long optimizations necessary in order to obtain the creation of motifs used for “guiding” of block copolymers by the processes reported in the literature.

1. A process for the preparation, by spatial distribution of light intensity, of a surface in relief promoting order and spatial coherence serving as a guide for the organization, on nano- and micrometre scales, of an overlayer on the surface comprising the following steps:
A: depositing a first solution or dispersion of at least one (co)-polymer containing at least one isomerizable functional group on a surface;
B: evaporating the solvent present in the first solution or dispersion;
C: irradiating the surface thus treated according to a spatial distribution of light intensity and creation of motifs possessing a periodic or non-periodic relief;
D: depositing a second solution or a dispersion on the surface thus treated, of at least one block copolymer, of which at least one of the three dimensions is less than the half-wavelength used for the irradiation of the surface; and
E: removing the solvent present in the second solution or dispersion by evaporation or reaction.

2. The process according to claim 1, wherein the (co)-polymer containing at least one isomerizable functional group contains at least one crosslinkable functional group and comprising an additional step C′ after the step C comprising crosslinking the (co)-polymer containing at least one isomerizable functional group and at least one crosslinkable functional group.

3. The process according to claim 1, wherein the block copolymer is a di-block copolymer.

4. The process according to claim 1, wherein the copolymer is a block copolymer in which at least one of the blocks is a degradable block.

5. The process according to claim 3, wherein the di-block copolymer is a PS-b-PMMA, a PS-b-PEO, PS-b-PDMS, PLA-b-PDMS or a PS-b-PLA.

6. The process according to claim 1, wherein the block copolymer is a tri-block copolymer.

7. The process according to claim 6, wherein the tri-block copolymer is a PLA-b-PDMS-b-PLA.

8. The process according to claim 1, wherein the isomerizable functional group is an azo functional group.

9. The process according to claim 2, wherein the crosslinkable functional group is an acrylic or methacrylic functional group.

10. The process according to claim 2, wherein the first solution or dispersion containing the isomerizable and crosslinkable (co)-polymer additionally contains a photoinitiator.

11. The process according to claim 10, wherein the photoinitiator is a cyanine.

12. The process according to claim 2, wherein the first solution or dispersion containing the isomerizable and crosslinkable (co)-polymer also contains a multifunctional monomer.

13. The process according to claim 12, wherein the multifunctional monomer is tris((2-acryloyloxy)ethyl)isocyanurate.

14. A surface obtained according to the process of claim 1.

15. A method for manufacturing surfaces useful in applications for holographic optical components; for the volume storage of data; for the production of surfaces or materials exhibiting photo-controlled deformation; for the creation of nanoporous or microporous structures for filtration membranes or for batteries; for surface coating in order to obtain super-hydrophobic surfaces, variegated surfaces, or antireflective surfaces, or surfaces exhibiting an opalescent effect; for the creation of optical or Plasmon waveguides on substrates; for the control of the transport properties of materials; for the production of templates on the nanometre scale, or as assembly guide for block copolymers on a surface, wherein the method comprises using a surface in accordance with claim 14.
